(19) United States
(12) Patent Application Publication
(10) Pub. No.: US 2008/0281539 A1
(43) Pub. Date: Nov. 13, 2008

(54) DETECTION AND CORRECTION OF ERRORS IN DEMODULATOR USING DIFFERENTIAL CALCULATIONS

(75) Inventors: Suzan Fishel, Cupertino, CA (US); Yu-Wen (Evan) Chang, Fremont, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: MediaPhy Corporation, San Jose, CA (US)

(21) Appl. No.: 12/113,785

(22) Filed: May 1, 2008

Related U.S. Application Data
(60) Provisional application No. 60/915,609, filed on May 2, 2007.

(51) Int. Cl. G01R 13/00

(52) U.S. Cl. 702/66

(57) ABSTRACT

Systems, methods, and devices are described for detecting and correcting errors. Samples are received representative of a wireless signal which includes a number of subcarriers. One or more of the subcarriers may be identified as a reference subcarrier, and the identification may be based on an energy measurement. A value for the reference subcarrier may be identified at a selected symbol. The value may be identified by calculating a difference measurement for the reference subcarrier between a previous, known symbol and the selected symbol. A difference measurement is then calculated between the identified subcarrier and a second subcarrier for the selected symbol. A determination may be made whether a decision for a subcarrier at the selected symbol is in error based on calculations which include the identified value and the difference measurement between the identified subcarrier and a second subcarrier. The decision in error may be corrected.

### CROSS REFERENCES

This application claims priority from co-pending U.S. Provisional Patent Application No. 60/915,609, filed May 2, 2007, entitled “DETECTION AND CORRECTION OF ERRORS IN COHERENT DEMODULATOR” (Attorney Docket No. 025950-000600US), which is hereby incorporated by reference, as if set forth in full in this document, for all purposes.

### BACKGROUND

The present invention relates to wireless communications in general and, in particular, to error correction and detection.

Orthogonal Frequency Division Multiplexing (“OFDM”) is a widely adopted signaling scheme for wireless communications, due at least in part to its robustness against the effects of multipath fading channel propagation. A basic concept of OFDM is to carry the modulated bit-streams on individual orthogonal subcarriers. This transmission technique is especially suited for mitigating the effect of the multipath fading channel that often occurs during mobile reception.

In certain implementations, differential quadrature phase shift keying (DQPSK) modulation may be used in OFDM and other systems to avoid channel estimation during demodulation. Use of DQPSK may be based in part on the assumption that the channel will change slowly over time. However, in high Doppler environments, the channel may vary more quickly, which may degrade the performance of DQPSK. Traditional methods and devices may have difficulties with coherent demodulation in such environments. Therefore, it may be desirable to have novel devices and methods for detecting the location of errors due to fast varying channels or other adverse channel conditions. Further, it may be desirable to identify novel devices and methods that may be used to correct such errors.

### SUMMARY

Systems, methods, and devices are described for detecting and correcting errors. In one embodiment, samples are received representative of a wireless signal which includes a number of subcarriers. One or more of the subcarriers are identified as a reference subcarrier, and the identification may be based on an energy measurement. A value for the reference subcarrier is identified at a selected symbol. The value may be identified by calculating a difference measurement for the reference subcarrier between a known symbol and the selected symbol. A difference measurement is then calculated between the identified subcarrier and a second subcarrier for the selected symbol.

A determination is made whether a decision for a value at one or more of the subcarriers at the selected symbol is in error based on calculations which include the identified value and the difference measurement between the identified subcarrier and a second subcarrier. The determination for a given subcarrier may, in addition, be based on calculations from a number of additional difference measurements between a series of subcarriers from the reference subcarrier to the subcarrier with the decision in error. The decision in error may be corrected.

### BRIEF DESCRIPTION OF THE DRAWINGS

A further understanding of the nature and advantages of the present invention may be realized by reference to the following drawings. In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 is a block diagram of a wireless system configured according to various embodiments of the invention.

FIG. 2 is a block diagram of a receiver device including components configured according to various embodiments of the invention.

FIG. 3 is a representation of an index illustrating a range of subcarriers over time for a multicarrier signal according to various embodiments of the invention.

FIG. 4 is a block diagram illustrating an example configuration for certain components of a demodulator unit configured according to various embodiments of the invention.

FIG. 5 is a block diagram illustrating an example configuration for certain components of a time differential calculation unit configured according to various embodiments of the invention.

FIG. 6 is a block diagram illustrating an example configuration for certain components of a frequency differential calculation unit configured according to various embodiments of the invention.

FIG. 7 is a block diagram illustrating an example configuration for certain components of a detection and correction unit configured according to various embodiments of the invention.

FIG. 8 is a flowchart illustrating a method of error detection according to various embodiments of the invention.

FIG. 9 is a flowchart illustrating a method of decision correction according to various embodiments of the invention.

FIG. 10 is a flowchart illustrating a method of error detection and correction according to various embodiments of the invention.

FIGS. 11A & B are flowcharts illustrating an alternative method of error correction according to various embodiments of the invention.

### DETAILED DESCRIPTION OF THE INVENTION

In various embodiments of the invention, a mobile communications device is described, and is configured to receive wireless OFDM signals including a number of subcarriers. Errors may occur in demodulating the received subcarriers, and such errors may be detected and corrected at the device according to such embodiments.

To do so, the device may identify one of the subcarriers as a reference subcarrier, and this identification may be based on an energy measurement. A value for the reference subcarrier is identified at a selected symbol. This value may be determined by using a difference measurement between a pilot symbol (or other known symbol) and the selected symbol at the reference subcarrier. A difference measurement is then calculated between the identified subcarrier and a second subcarrier for the selected symbol, and used with the identified value to determine whether a first decision at an adjacent subcarrier is in error. A number of additional difference measurements between subcarriers may be used to make additional error decisions, leveraging results of the determination. Novel techniques to correct the decision in error are described, as well.

The following description provides examples only, and is not intended to limit the scope, applicability, or configuration of the invention. Rather, the ensuing description of the embodiments will provide those skilled in the art with an enabling description for implementing embodiments of the invention. Various changes may be made in the function and arrangement of elements without departing from the spirit and scope of the invention.

Thus, various embodiments may omit, substitute, or add various procedures or components, as appropriate. For instance, it should be appreciated that in alternative embodiments, the methods may be performed in an order different from that described, and that various steps may be added, omitted, or combined. Also, features described with respect to certain embodiments may be combined in various other embodiments. Different aspects and elements of the embodiments may be combined in a similar manner.

It should also be appreciated that the following systems, methods, and software may individually or collectively be components of a larger system, wherein other procedures may take precedence over or otherwise modify their application. Also, a number of steps may be required before, after, or concurrently with the following embodiments.

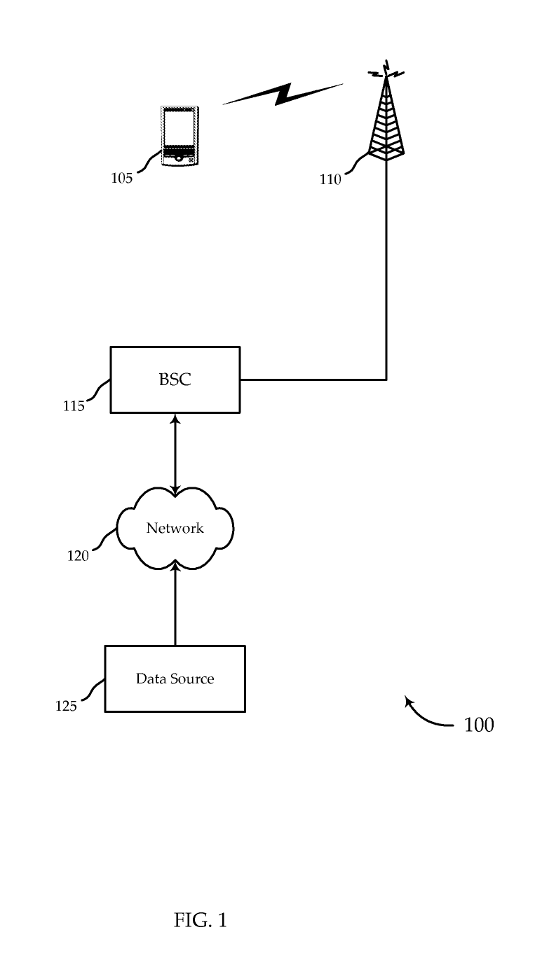

Systems, devices, and methods are described for the identifying errors in demodulation and making corrective decisions. Turning to FIG. 1, an example communications system 100 for implementing embodiments of the invention is illustrated. The system includes a communications device 105. The communications device 105 may be a cellular telephone, other mobile phone, personal digital assistant (PDA), portable video player, portable multimedia player, portable DVD player, laptop personal computer, a television in transportation means (including cars, buses, and trains), portable game console, digital still camera or video camcorder, or other device configured to receive wireless communications signals.

In the illustrated embodiment, the device 105 communicates with one or more base stations 110, here depicted as a cellular tower. A base station 110 may be one of a collection of base stations utilized as part of a system 100 that communicates with the device using wireless signals. Thus, the communications device 105 may receive wireless signals from the base station 110, and detect and correct errors which occur in demodulating the signal according to embodiments of the invention. These novel detection and correction techniques will be described in detail below.

The base station 110 is in communication with a Base Station Controller (BSC) 115 that routes the communication signals between the network 120 and the base station 110. In other embodiments, other types of infrastructure network devices or sets of devices (e.g., servers or other computers) may also serve as an interface between a network 120 and the base station 110. For example, a BSC 115 may communicate with a Mobile Switching Center (MSC) that can be configured to operate as an interface between the device 105 and a Public Switched Telephone Network (PSTN).

The network 120 of the illustrated embodiment may be any type of network, and may include, for example, the Internet, an IP network, an intranet, a wide-area network (WAN), a local-area network (LAN), a virtual private network (VPN), the Public Switched Telephone Network (PSTN), or any other type of network supporting data communication between any devices described herein. A network 120 may include both wired and wireless connections, including optical links. The system 100 also includes a data source 125, which may be a server or other computer configured to transmit data (video, audio, or other data) to the communications device 105 via the network 120.

It is worth noting that aspects of the present invention may be applied to a variety of devices (such as communications device 105) generally and, more specifically, may be applied to mobile digital television (MDTV) devices. Aspects of the present invention may be applied to digital video broadcast standards that are either in effect or are at various stages of development. These may include the European standard DVB-H, the Japanese standard ISDB-T, the Korean standards digital audio broadcasting (DAB)-based Terrestrial-DMB and Satellite-DMB, the Chinese standards DTV-M, Terrestrial-Mobile Multimedia Broadcasting (T-MMB), Satellite and terrestrial interaction multimedia (STiMi), and the MediaFLO format proposed by Qualcomm Inc. While the present invention is described in the context of the DMB standard, it may also be implemented in any of the above or future standards, and as such is not limited to any one particular standard.

In one embodiment, the system 100 is an OFDM system. It is worth noting, however, that some embodiments of the invention are applicable to other multicarrier systems. At the base station 110 of such a system, the QAM symbols may be modulated by means of an IFFT (inverse fast fourier transform) on N parallel subcarriers, and then the transmitted signal xₙ(m) can be expressed as follows:

$${x}_{n} ( m ) = {\sum }_{k = 0}^{N - 1} {X}_{n , k} {e}^{j 2 π m \frac{{kT}_{s}}{{T}_{s} N}} \qquad Eq . 1$$

where X_{n,k} represents the QAM symbol in the k^{th} subcarrier during the n^{th} symbol period, N and Tₛ represent the number of subcarriers and the duration of an OFDM symbol, respectively.

At the receiver, the received signal rₙ(m) can be expressed as:

$${r}_{n} ( m ) = {\sum }_{i = 0}^{L - 1} {x}_{n} ( m - {τ}_{i} ) {ρ}_{i} {e}^{\{ j 2 π ( \frac{k}{{T}_{s}} + ɛ ) \frac{{T}_{s}}{N} m + {θ}_{i} \}} + w ( m ) \qquad Eq . 2$$

where L is the number of multipath, w(m) represents the additive white Gaussian noise (AWGN), ε is the frequency offset, and ρᵢ, θᵢ and τᵢ represent the amplitude attenuation, the phase shift, and the relative delay corresponding to the i^{th} path, respectively.

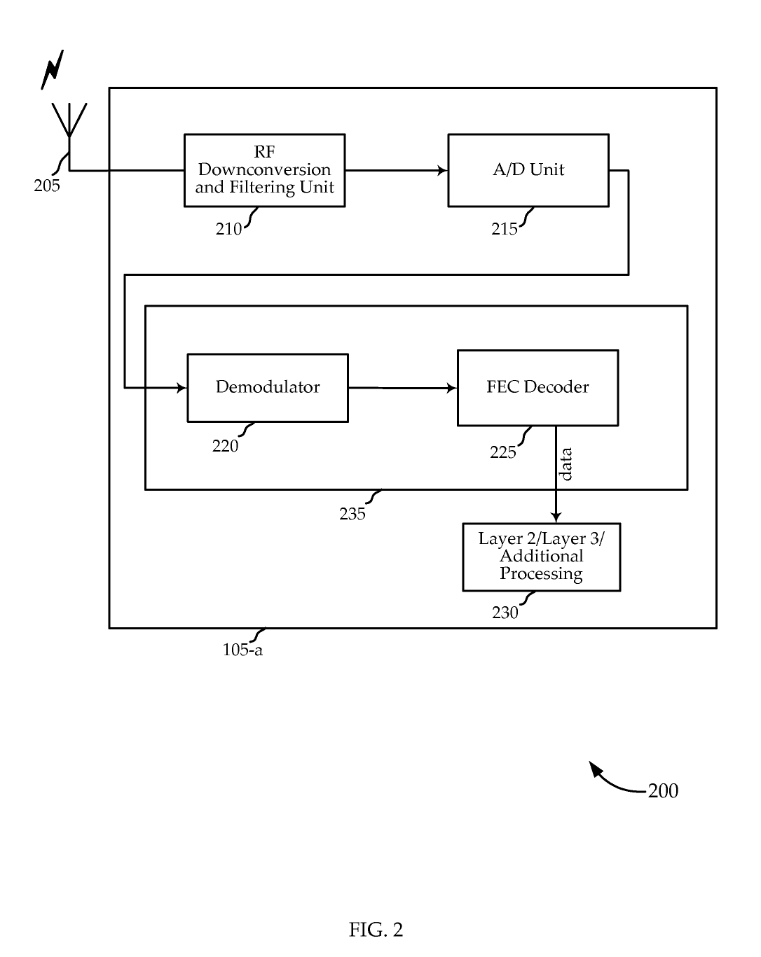

Referring to FIG. 2, an example block diagram 200 of a device 105-a is shown which illustrates various embodiments of the invention. The device 105-a may be the communications device of FIG. 1. In the embodiments described herein, assume an orthogonal frequency division multiplexing (OFDM) system is implemented, while realizing that the principles described are applicable to a multicarrier signal in a range of both wireless and wireline systems. Also, while an assumption will be made that the system at issue implements DMB using DQPSK, embodiments of the invention may be implemented in a range of other systems.

The device 105-a includes a number of receiver components, which may include: an RF down-conversion and filtering unit 210, A/D unit 215, demodulator unit 220, and FEC decoder unit 225. These units of the device 105-a may, individually or collectively, be implemented with one or more Application Specific Integrated Circuits (ASICs) adapted to perform some or all of the applicable functions in hardware. Alternatively, the functions may be performed by one or more other processing units (or cores), on one or more integrated circuits. In other embodiments, other types of integrated circuits may be used (e.g., Structured/Platform ASICs, Field Programmable Gate Arrays (FPGAs), and other Semi-Custom ICs), which may be programmed in any manner known in the art. The functions of each unit may also be implemented, in whole or in part, with instructions embodied in a memory, formatted to be executed by one or more general or application-specific processors. The device 105-a may include one or more memory units (not shown) used for a variety of purposes.

In one embodiment, the radio frequency signal is received via an antenna 205. The desired signal is selected and down-converted and filtered through the RF down-conversion and filtering unit 210. The output of that unit 210 is the analog baseband (or passband at much lower frequency than the original radio frequency) signal, which is converted into digital signal by the A/D unit 215. At the demodulator unit 220, the digital signal is received and processed to produce a stream of data. The demodulator unit 220 may perform symbol synchronization, FFT processing, frequency offset correction and estimation, and equalizer functions in a variety of combinations known in the art. The demodulator unit 220 may also perform the error detection and correction techniques according to embodiments of the invention.

Detected error data which has been corrected may be forwarded to an FEC decoder unit 225, which may decode the signal and output a stream of data (note that the data may be further processed by other components of the demodulator unit 220 before being forwarded to FEC decoder unit 225, and in some embodiments the transmitted data need not be encoded so there need not be a FEC decoder unit 225). This data stream may be forwarded to a layer 2/layer 3/additional processing unit 230 for further processing. It is worth noting that in one embodiment, the demodulator unit 220 and FEC decoder unit 225 are receiver components 235 implemented in a single PHY chip. It is also worth noting that in another embodiment, the RF down-conversion and filtering unit 210, A/D unit 215, demodulator unit 220, and FEC decoder unit 225 are implemented in a single chip with RF and PHY functionality.

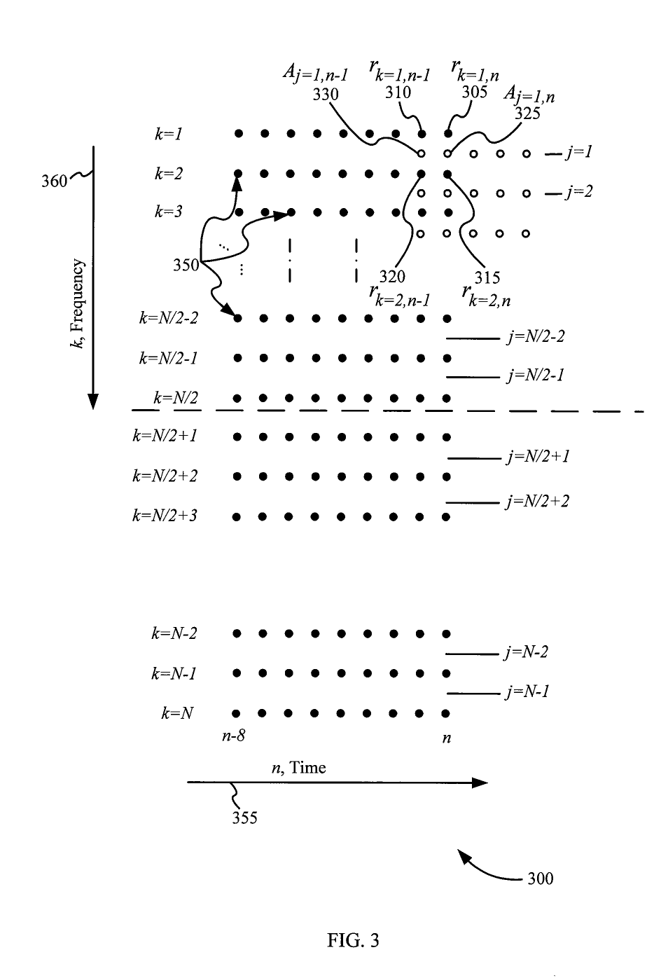

Turning to FIG. 3, an index 300 for N subcarriers over a number of symbols is illustrated. Thus, the vertical axis 360 represents frequency, and the horizontal axis represents time 355. These subcarriers k may be the subcarriers for an OFDM signal received according to the description relating to the device 105 in FIG. 1 or 2, although certain principles are applicable to a range of multicarrier systems. Each black circle 350 represents a data cell (which, for purposes of discussion, may include pilot cells). The index will be used to describe certain embodiments.

The index illustrates a simplified time domain representation of certain subcarriers over adjacent symbols. For example, reference numeral 305 illustrates r_{k=1, n} and reference numeral 310 illustrates previous time sample r_{k=1, n-1} for the subcarrier k. For purposes of example, assume a simplification of aspects of Eq. 2. A received sample post FFT for subcarrier k at time n may be represented as r_{k,n}=H_{k,n}x_{k,n}, where H is the channel coefficient and x represents the original transmitted constellation. In the time direction, it can be assumed in certain conditions that the channel difference between two consecutive (or nearby) time samples ∠(H_{k,n}H*_{k,n-1})≅0. This is because in certain environments, the channel for each of two adjacent (or nearby) time samples will be very similar. Consider first the case of a carrier, k+1, over consecutive time samples, r_{k=1, n} 305, and r_{k=1, n-1} 310. In this case, multiplying r_{k=1,n} by the conjugate of r_{k=1,n-1} provides a difference measurement at subcarrier k for a received signal at the pair of consecutive samples. Assuming a slowly varying channel, the following equation results:

\hat{d}_{k,n}=r_{k,n}r*_{k,n-1}=H_{k,n}H*_{k,n-1}x_{k,n}x*_{k,n-1}≅x_{k,n}x*_{k,n-1}. Eq. 3

Therefore, the likelihood that consecutive time samples for a carrier have flat channel characteristics may be leveraged to effectively cancel the impact of the channel and retrieve x_{k=1,n} and the conjugate of x_{k=1,n-1}. This principle may be applied to instances concerning time samples in the other time direction (e.g., r_{k=1,n}r*_{k=1,n+1}=H_{k=1,n}H*_{k=1,n+1}x_{k=1,n}x*_{k=1,n+1}≅x_{k=1,n}x*_{k=1,n+1}). This principle may also be applied in certain circumstances to nearby time samples (e.g., r_{k, n} with r_{k, n-2}, or rₖ with r_{k, n+3}). While in one embodiment, therefore, the difference measurement between r_{k=1,n} and r_{k=1, n-1} maybe calculated using r_{k=1,n}r*_{k=1,n-1}≅x_{k=1,n}x*_{k=1,n-1}, other difference measures may be used in other embodiments. However, while the above may hold true in flat channel environments, in high Doppler environments or in conditions where the channel is otherwise quickly time-varying, this assumption will be less likely to be valid.

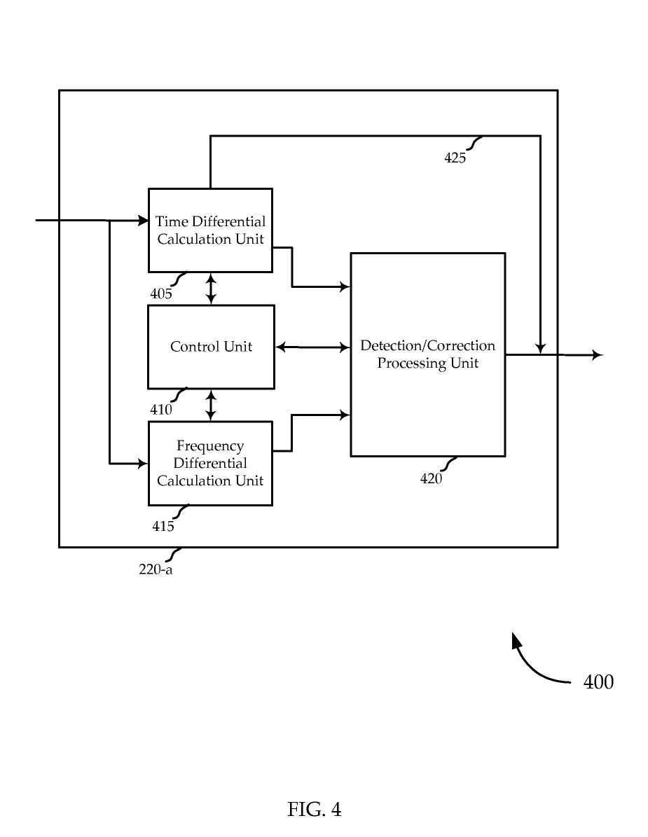

Turning to FIG. 4, a block diagram 400 illustrates an example of certain functional components of a demodulator unit 220-a. The demodulator unit 220-a may be the demodulator unit 220 of FIG. 2. In the illustrated embodiment, the demodulator unit 220-a includes a time differential calculation unit 405, a control unit 410, a frequency differential calculation unit 415, and a detection/correction processing unit 420.

In one embodiment, the demodulator unit 220-a receives samples (e.g., complex samples) representative of a wireless signal which includes a number of subcarriers (perhaps an OFDM signal received from A/D unit 215 of FIG. 2). The time differential calculation unit 405 may receive the samples, and identify one or more of the subcarriers as a reference subcarrier. This identification may be based on an energy measurement. The time differential calculation unit 405 may identify or estimate value for the reference subcarrier at a selected symbol. The value may be identified by calculating a first difference measurement for the reference subcarrier between a known symbol (e.g., a known pilot symbol or otherwise known subcarrier at the symbol) and the selected symbol. A frequency differential calculation unit 415 may also receive the samples, and calculate a second difference measurement between the identified subcarrier and a second subcarrier for the selected symbol.

A detection/correction processing unit 420 may then make a determination whether a decision for a value at a subcarrier at the selected symbol is in error, the determination based on a series of calculations which include the identified value and the difference measurement between the identified subcarrier and a second subcarrier. The determination for a given subcarrier may, in addition, be based on calculations (e.g., by the frequency differential calculation unit 415) for a number of additional difference measurements between a series of subcarriers from the reference subcarrier to the subcarrier with the decision in error. The decision in error may be corrected by the detection/correction processing unit 420.

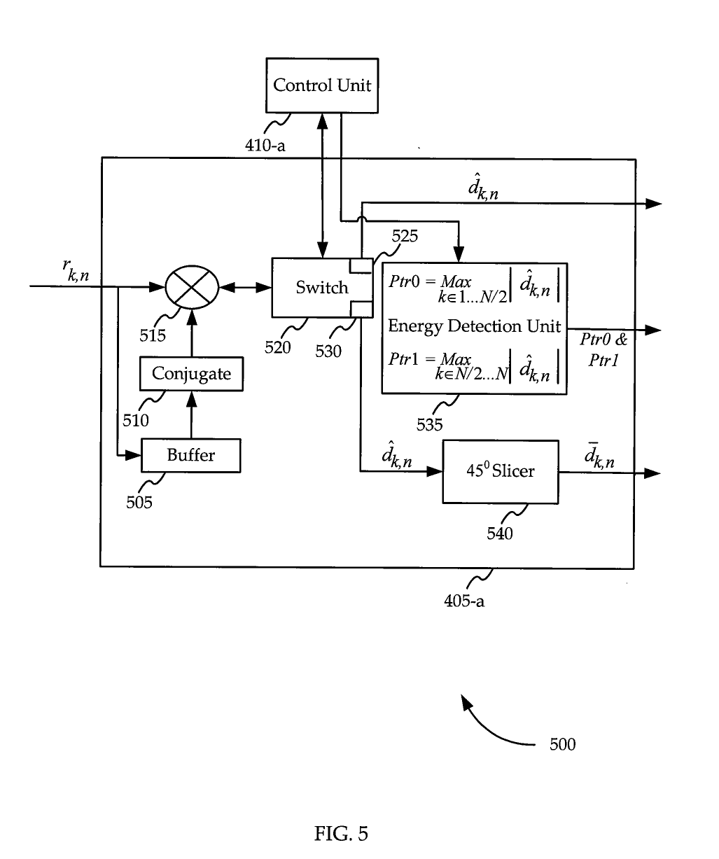

FIG. 5 is a block diagram 500 illustrating an example configuration of a time differential calculation unit 405-a. This time differential calculation unit 405-a may be the time differential calculation unit 405 of FIG. 4. To further explain certain embodiments, consider incoming signal r_{k,n}. Upon entering the unit 405-a, r_{k,n} is buffered at buffer unit 505 (or there may be delay lines or other buffering functionality known in the art). A conjugate unit 510 takes the complex conjugate of the buffered signal. At block 515, the presently incoming signal is multiplied by the complex conjugate of the buffered signal. Control unit 410-a will then make a determination whether the current environment is above a certain threshold related to a measurement of Doppler and/or the rate over time of channel variation. A number of metrics may be used to make such a determination, and the control unit may make the measurement or receive it from another source. The threshold may vary dynamically based on ongoing measurements. The interval between measurements may vary based on the recent measurements (i.e., after periods of stability, taking fewer measurements).

Based on the determination by the control unit 410-a, a switch 520 may have different outputs. If the Doppler/fast varying channel measurement is below the threshold, the switch 520 may output 525 a soft decision \hat{d}_{k,n} (e.g., to the FEC decoder 225 of FIG. 2), bypassing further processing by certain components in the demodulator unit 220 (e.g., an output 425 bypassing the detection/correction processing unit 420 of FIG. 4). This switch output port may be controlled by the control unit 410-a or switch 520. Recall Eq. 3, where \hat{d}_{k=1,n}=r_{k=1,n}r*_{k=1,n-1}=H_{k=1,n}H*_{k=1,n-1}x_{k=1,n}x*_{k=1,n-1}≅x_{k=1,n}x*_{k=1,n-1} in the appropriate conditions. Assuming that the previous time sample for the subcarrier is known, Eq. 3 provides the x_{k,n}. This procedure can be performed across N carriers, for consecutive time samples. Therefore, in one embodiment, the sub-block is processed within one symbol duration.

Alternatively, if the Doppler/fast varying channel measurement is above the threshold, the time differential calculation unit 405 may perform additional processing to output a hard decision d̅_{k,n}. Thus, the threshold may be set at a point above which the assumption of a flat channel over time is invalid. The switch 520 may in this event output 530 a soft decision \hat{d}_{k,n} to a 45° slicer 540, to produce thereby a hard decision d̅_{k,n} to be output for further processing to the detection/correction processing unit 420 (as illustrated in FIG. 4). As noted above, this switch output port may be controlled by the control unit 410-a or switch 520. When the value for a subcarrier at the previous symbol is known (e.g., because it is pilot, or has been corrected), \hat{d}_{k,n} may be the difference measurement used to estimate a value for the subcarrier at the later arriving data symbol, and d̅_{k,n} may be an estimated value for the subcarrier.

Also, when the Doppler/fast varying channel measurement is above the threshold, the control unit 410-a or switch 520 may control an energy detection unit 535 to perform energy detection over the N carriers. In one embodiment, two carrier locations are identified, Ptr0 & Ptr1, where maximum energy is detected from 1 to N/2 and N/2+1 to N respectively. The subcarriers where maximum energy is detected may then be used as reference subcarriers. Note that in other embodiments, there may be more or fewer pointers, and the procedures for detecting maximum energy may vary (e.g., there may be an average over time, or there may be other factors which dictate the selection of particular pointers). Nonetheless, in the example embodiment, Ptr0 & Ptr1 are forwarded (e.g., from energy detection unit 535 or control unit 410) for further processing to the detection/correction processing unit 420 (as illustrated in FIG. 4). It is, however, worth noting that in one embodiment, there need not be a threshold, or the threshold may be very low (for example, where reliability is a concern). Also, different novel elements described herein may be combined in various ways not detailed herein.

Turning back momentarily to FIG. 4, assume an example in which the Doppler/fast varying channel measurement is above the threshold. The control unit 410 may control the frequency differential calculation unit 415 to receive r_{k,n} and one or more adjacent or nearby subcarriers (perhaps received from A/D unit 215 of FIG. 2). In one embodiment, the received signal is a series of complex samples representative of the wireless signal. The frequency differential calculation unit 415 may be configured to calculate a difference measurement between a subcarrier and an adjacent subcarrier for a selected data symbol. This difference measurement, between carriers, will now be discussed in greater detail.

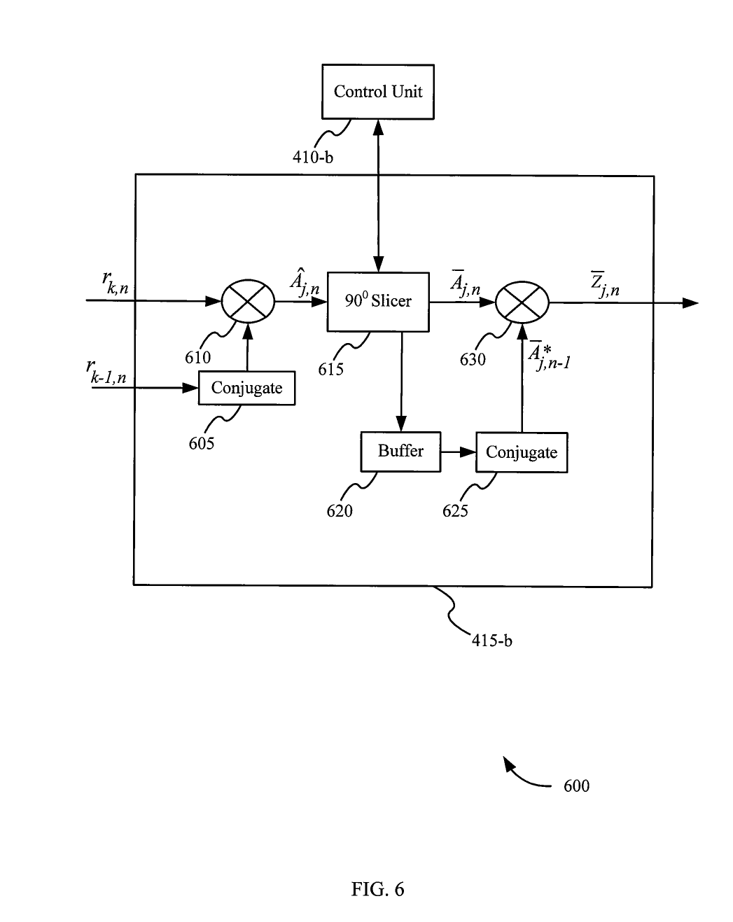

FIG. 6 is a block diagram 600 illustrating an example of the frequency differential calculation unit 415-b, and the difference measurements that may be calculated therein. In the illustrated embodiment, adjacent subcarriers r_{k,n} and r_{k,n-1} are received by the frequency domain processing unit 415-b. For purposes of example, again assume a simplification of aspects of Eq. 2. A received sample post FFT for subcarrier k at time n may be represented as r_{k,n}=H_{k,n}x_{k,n}, where H is the channel coefficient and x represents the original transmitted constellation. On the frequency direction, it may be assumed that the channel difference between two consecutive (or nearby) subcarriers ∠(H_{k,n}H*_{k-1,n})≅0. This is because the channel for each of two adjacent (or nearby) subcarriers may be very similar, even in the face of a high Doppler/fast varying channel environment.

For purposes of explanation, again refer to FIG. 3. Consider first the case of adjacent subcarriers, r_{k=1,n} 305 and r_{k=2,n} 315. In this case, multiplying r_{k=1,n} 305 by the complex conjugate of r_{k=2,n} 315 provides a difference measurement of received signal at the pair of subcarriers. The following equation applies:

r_{k,n}r*_{k-1,n}=H_{k,n}H*_{k-1,n}x_{k,n}x*_{k-1,n}≅x_{k,n}x*_{k-1,n}. Eq. 4

Therefore, the likelihood that adjacent carriers have flat channel characteristics may be leveraged to effectively cancel the impact of the channel and retrieve the product of x_{k=1,n} and the conjugate of x_{k=2,n}. Thus, in the example, assume r_{k=1,n} and r_{k=2,n} are received, then the product of x_{k=1,n} and the conjugate of x_{k=2,n} may be calculated. If one of the subcarriers at a symbol is known, determined, or otherwise calculated (e.g., x_{k=2,n} is known), x_{k=1,n} may be calculated (e.g., x_{k=1,n}=r_{k=1,n}r*_{k=2,n}/x*_{k=2,n}). This principle may be applied to instances concerning adjacent subcarriers in the other frequency direction (e.g., r_{k,n}r*_{k+1,n}=H_{k,n}H*_{k+1,n}x_{k,n}x*_{k+1,n}≅x_{k,n}x*_{k+1,n}). This principle may also be applied in certain circumstances to nearby subcarriers (e.g., rₖ 310 with rₖ₋₂, or rₖ 310 with rₖ₊₃). While in one embodiment, therefore, the difference measurement between r_{k,n} and r_{k-1,n} may be calculated using r_{k,n}r*_{k-1,n}≅x_{k,n}x*_{k-1,n}, other difference measures may be used in other embodiments. While we have shown that the difference measurement between r_{k,n} and r_{k-1,n} may be used directly to identify the correct value for an adjacent subcarrier x_{k-1,n}, it may be used indirectly as well. For example, the correct value for the adjacent subcarrier x_{k-1,n} may be used, with a new difference measurement between r_{k-1,n} and r_{k-2,n}, to determine the correct value x_{k-2,n} (thus, by using the initial difference measurement and the first correct value to make a decision for the adjacent subcarrier x_{k-1,n}, these calculations also are indirectly used in additional difference measurements and decisions or error detection for other subcarriers).

With this description, again refer to FIG. 6, in which a block diagram illustrating an embodiment of the frequency differential calculation unit 415-b is shown. In the illustrated embodiment, again note adjacent subcarriers r_{k,n} and r_{k-1,n} are received by the frequency domain processing unit 415. At conjugate unit 605, the conjugate of the r_{k-1,n} is taken. At block 610, the presently incoming signal for the k carrier is multiplied by the complex conjugate of the buffered signal. Noting the calculations from Eq. 4, note the following equation for an Â_{j,n}:

Â_{j,n}=r_{k,n}r*_{k-1,n}≅x_{k,n}x*_{k-1,n}. Eq. 5

The Â_{j,n} term output from the multiplier block 610 is sent to the 90° slicer block 615, which outputs a hard decision Ā_{j,n}. Assuming that one of x_{k,n} or x_{k-1,n} is known (e.g., has been corrected, determined, or is otherwise known), the Â_{j,n} or Ā_{j,n} terms may be the difference measurements used to detect an error, verify a correct decision, or calculate a value for the adjacent subcarrier.

Note that the Â_{j,n} term may be better understood with additional reference to the index 300 of FIG. 3. For example, multiplying r_{k=1,n} 305 and r*_{k=2,n} (the conjugate of r_{k=2,n} 315) is illustrated by A_{j=1,n} 325. Similarly, multiplying r_{k=1,n-1} 310 and r*_{k=2,n-1} (the conjugate of r_{k=2,n-1} 320) is illustrated by A_{j=1,n-1} 330.

The output Ā_{j,n} from 90° slicer block 615 is buffered at buffer unit 620 (or there may be delay lines or other buffering functionality known in the art). A conjugate unit 625 takes the complex conjugate of the buffered signal. At block 630, the presently incoming Ā_{j,n} signal is multiplied by the complex conjugate of the buffered signal Ā*_{j,n-1} to produce thereby the Z̅_{j,n} term. This procedure can be performed across N carriers, for consecutive time samples. Thus, the Z̅_{j,n} term may be considered an additional difference measurement between the previous symbol and the current symbol at additional subcarriers. As will be illustrated below, such additional difference measurements may be used in the determination that a decision identifying a value at an adjacent subcarrier is in error. In one embodiment, the sub-block is processed within one symbol duration. The Z̅_{j,n} term may be output for further processing to the detection/correction processing unit 420 (as illustrated in FIG. 4). The Z̅_{j,n} term in one embodiment is, therefore, given by the following equation:

Z̅_{j,n}=Ā_{j,n}Ā*_{j,n-1}. Eq. 6

Thus, in one embodiment of the invention, consider a received symbol r_{k,n} which includes N carriers (represented by N complex samples) for purposes of example. Referring to FIG. 4, output of the time domain processing unit 405 d̅_{k,n} or \hat{d}_{k,n} (e.g., depending on whether the Doppler/channel variation threshold is exceeded) are N complex samples. The intermediate values in the frequency domain processing unit 415, Â_{j,n}, Ā_{j,n} and Z̅_{j,n}, are N−1 complex values. Ā_{j,n} and Z̅_{j,n} are hard decision complex values (1,j,−1,−j), and the index j=1 is associated with the first sample of Ā_{j,n} and Z̅_{j,n}. As noted above, d̅_{k,n} and Z̅_{j,n} may be output to the detection/correction processing unit 420.

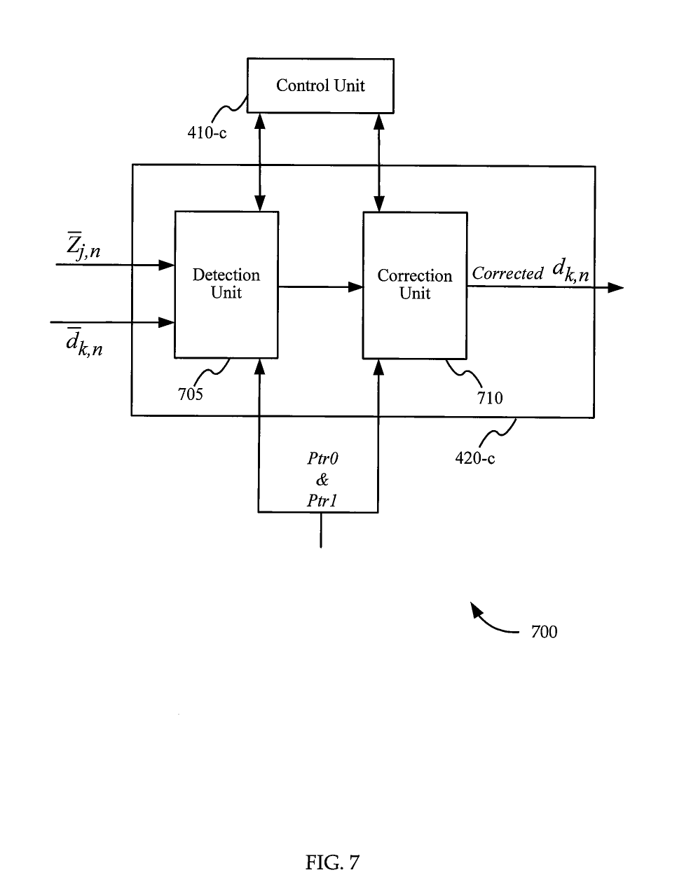

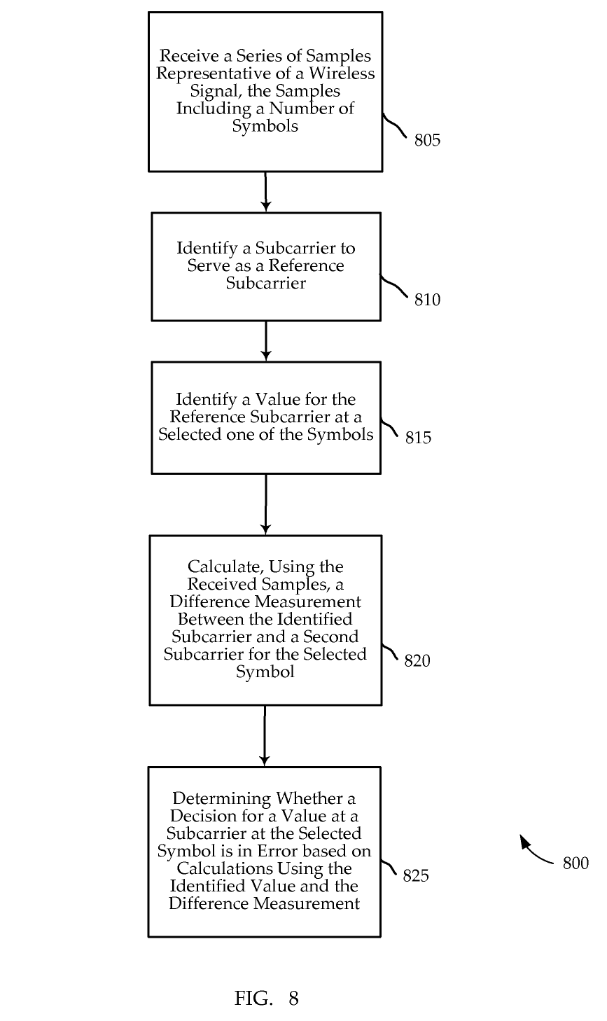

FIG. 7 is a block diagram 700 illustrating an embodiment of a detection/correction unit 420-c, which may be the detection/correction unit 420 of FIG. 4. FIG. 7 shows d̅_{k,n} and Z̅_{j,n} being received by the detection unit 705 of the detection/correction processing unit 420. While there are a number of variations available, the following describes one manner of detecting error; namely, the detection unit 705 calculates the following:

Zd_{k,n}= Z̅_{j,n} d̅_{k-1,n}( Z̅*_{j+1,n} d̅_{k+1,n})*. Eq. 7

In one embodiment, for each subcarrier to be checked (for error detection purposes), the detection unit 705 calculates the following:

$$E = {\sum }_{k = I - 1}^{k = I + 1} \vert imag ( {Zd}_{k , n} ) \vert \neq 0 \qquad Eq . 8$$

Thus, for the subcarrier I, and both adjacent subcarriers, if the sum from Eq. 8 is not 0, an error is detected for subcarrier I. Thus, referring to Eq. 7 and 8, a first difference measurement for the reference subcarrier between a known symbol and a later symbol is used to estimate a value for the reference subcarrier at the selected data symbol (see discussion related to d̅_{k,n} above). Also, again referring to Eq. 7 and 8, a second difference measurement between a reference subcarrier and a second subcarrier for the selected data symbol is used to detect an error for the second subcarrier at the selected data symbol (see discussion related to Ā_{j,n} above, as it relates to the Z̅_{j,n} term). Moreover, note that the Z̅_{j,n} term(s) may be considered additional difference measurement(s) between the previous symbol and the current symbol at additional subcarriers, and note that it is used in the detection scheme as well. While Eq. 8 uses a number of difference measurements, note that in other embodiments described herein only a subset of such measurements need be used for purposes of detection.

In one embodiment, the detection unit 705 begins detecting at each reference subcarrier Ptr0 & Ptr1 (where the maximum energy is detected from 1 to N/2 and N/2+1 to N respectively by the time domain processing unit 405), and progresses in both directions from each reference subcarrier across subcarriers. Thus, additional difference measurements for subcarriers between a reference subcarrier and one or more subcarriers with errors may be calculated, and used in detection. Thus, error detection decisions for the symbol may be based on a series of calculations made up of difference measurements from a reference subcarrier across subcarriers, along with the initial estimated value at the reference subcarrier. Intermediate subcarrier values (e.g., between the reference subcarrier carrier and a second subcarrier of interest) may be identified through verification or correction, and these intermediate values may be used with the additional difference calculations for error detection and correction. Thus, in some embodiments, the values of each subcarrier are built from knowledge of the reference subcarrier, and developed across subcarriers using this initial knowledge and a series of difference measurements.

In other embodiments, the detection unit 705 begins detecting from another point(s) or in other ordering schemes. A number of orders or progressions through the subcarriers are possible. In some embodiments, only a subset of subcarriers is checked. The detection calculation may operate without the correction scheme described herein, or utilize only aspects thereof.

If an error is detected through the above process (or perhaps through another detection process), data from the detection unit 705 may be forwarded to the correction unit 710. In one embodiment, the correction unit 705 begins correcting in both directions from Ptr0 & Ptr1 (where the maximum energy is detected from 1 to N/2 and N/2+1 to N respectively by the time differential calculation unit 405). In one embodiment, the subcarriers where maximum energy is detected provide a better likelihood that the time domain processing (e.g., using Eq. 3) will provide accurate decisions. In other embodiments, the correction unit 710 begins detecting and/or correcting from another point(s) or in other ordering schemes (e.g., additional pointers, other methods to identify valid starting point or points, modified correction equations, etc.). Thus, the maximum energy subcarrier(s) may effectively provide a reference calculation to use in correcting remaining subcarriers, although other reference calculations may be determined in other manners, as well.

One embodiment of the correction calculation is as follows, and may be implemented with or without all or part of the detection process described above. Using the equations from above, note the following:

$$\begin{matrix}{\overline{Z}}_{j , n} = {\overline{A}}_{j , n} {\overline{A}}_{j , n - 1}^{*} = \\ = {H}_{k , n} {H}_{k - 1 , n}^{*} {x}_{k , n} {{x}_{k - 1 , n}^{*} ( {H}_{k , n - 1} {H}_{k - 1 , n - 1}^{*} {x}_{k , n - 1} {x}_{k - 1 , n - 1}^{*} )}^{*} = \\ = \overline{{x}_{k , n} {x}_{k , n - 1}^{*}} {( \overline{{x}_{k - 1 , n} {x}_{k - 1 , n - 1}^{*}} )}^{*} \\ ≅ {\overline{d}}_{k , n} {\overline{d}}_{k - 1 , n}^{*} .\end{matrix} \qquad Eq . 9$$

Therefore, modifying Eq. 9 provides the following:

Corrected d_{k,n}= Z̅_{j,n} d̅_{k-1,n} Eq. 10

for correcting errors (or simply calculating the correct d_{k,n}) in a first direction. Modifying Eq. 9 also provides the following:

Corrected d_{k,n}= Z̅*_{j+1,n} d̅_{k+1,n} Eq. 11

for correcting errors (or simply calculating the correct d_{k,n}) in a second direction. Thus, referring to Eq. 10 and 11, a first difference measurement for the reference subcarrier between a known symbol and a later symbol is used to estimate a value for the reference subcarrier, and thus the first difference measurement and the estimated value may be used in calculations to determine or correct a value for another subcarrier at the selected data symbol (see discussion related to d̅_{k,n} above). Also, again referring to Eq. 10 and 11, a second difference measurement between a reference subcarrier and a second subcarrier for the selected data symbol may be used in calculations to determine or correct a value for a subcarrier (see discussion related to Ā_{j,n} above, as it relates to the Z̅_{j,n} term). Moreover, note that the Z̅_{j,n} term(s) may be considered additional difference measurement(s) between the previous symbol and the current symbol at additional subcarriers, and note that it is used in the example correction scheme as well. While Eq. 10 and 11 use a number of difference measurements, note that in other embodiments described herein only a subset of such measurements need be used for purposes of detection.

The following pseudocode in Table 1 provides an example of an implementation according to one embodiment of the invention:

TABLE 1

for I = Ptr1 + 1 [symbol] N − 1, increment = 1

$if {\sum }_{k = I - 1}^{k = I + 1} {Zd}_{k , n} \neq 0$

for k = I − 1 [symbol] I + 1

Corrected d_{k,n} = Z̅_{j,n} d̅_{k-1,n}

end;

endif

endfor
for I = Ptr1 − 1 [symbol] N/2 + 2, decrement = −1

$if {\sum }_{k = I + 1}^{k = I - 1} {Zd}_{k , n} \neq 0$

for k = I + 1 [symbol] I − 1

Corrected d_{k,n} = Z̅*_{j+2,n} d̅_{k+1,n}

end;

endif

endfor
for I = Ptr0 + 1 [symbol] N/2 − 1, increment = 1

$if {\sum }_{k = I - 1}^{k = I + 1} {Zd}_{k , n} \neq 0$

for k = I − 1 [symbol] I + 1

Corrected d_{k,n} = Z̅_{j,n} d̅_{k-1,n}

end;

endif

endfor
for I = Ptr0 − 1 [symbol] 2, decrement = −1

$if {\sum }_{k = I + 1}^{k = I - 1} {Zd}_{k , n} \neq 0$

for k = I + 1 [symbol] I − 1

Corrected d_{k,n} = Z̅*_{j+1,n} d̅_{k+1,n}

end;

endif

endfor

The demodulator unit 220 of FIG. 2 or 4 may operate in a number of modes to account for different standards. For example, the demodulator unit 220 may operate in a first mode wherein the known symbol is a first pilot signal for one standard (e.g., DMB), and operate in a second mode wherein the known symbol is a second pilot signal for another standard (ISDB). The demodulator unit 220 may be configured to operate when all, or only a portion, of the waveform is known at the receiver. Therefore, a variety of pilot signals may be used with the differential calculation described above to perform the correction and detection techniques described above.

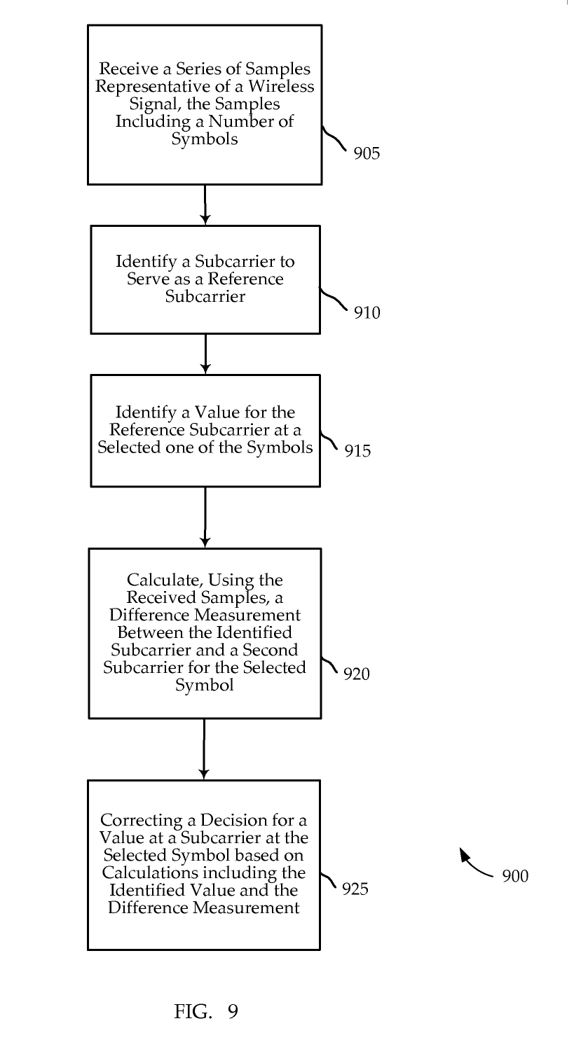

FIG. 8 is a flowchart illustrating a method 800 of error detection according to various embodiments of the invention. The method 800 may, for example, be performed in whole or in part on the mobile communications device 105 of FIG. 1 or 2 or, more specifically, the demodulator 220 of FIG. 2 or 4.

At block 805, a series of samples representative of a wireless signal is received, the samples including a number of symbols. At block 810, a subcarrier is identified to serve as a reference subcarrier. At block 815, a value is identified for the reference subcarrier at a selected one of the symbols. At block 820, using the received samples, a difference measurement between the identified subcarrier and a second subcarrier is calculated for the selected symbol. At block 825, a determination is made whether a decision for a value at a subcarrier at the selected symbol is in error, the determination made based on calculations using the identified value and the difference measurement. This method 800 may be performed utilizing Eqs. 7 and 8.

FIG. 9 is a flowchart illustrating a method 900 of error correction according to various embodiments of the invention. The method 900 may, for example, be performed in whole or in part on the mobile communications device 105 of FIG. 1 or 2 or, more specifically, the demodulator 220 of FIG. 2 or 4.

At block 905, a series of samples representative of a wireless signal is received, the samples including a number of symbols. At block 910, a subcarrier is identified to serve as a reference subcarrier. At block 915, a value for the reference subcarrier at a selected one of the symbols is identified. At block 920, using the received samples, a difference measurement between the identified subcarrier and a second subcarrier is calculated for the selected symbol. At block 925, a decision for a value at a subcarrier at the selected symbol is corrected based on a calculation including the identified value and the difference measurement. This method 900 may be performed utilizing Eqs. 10 and 11.

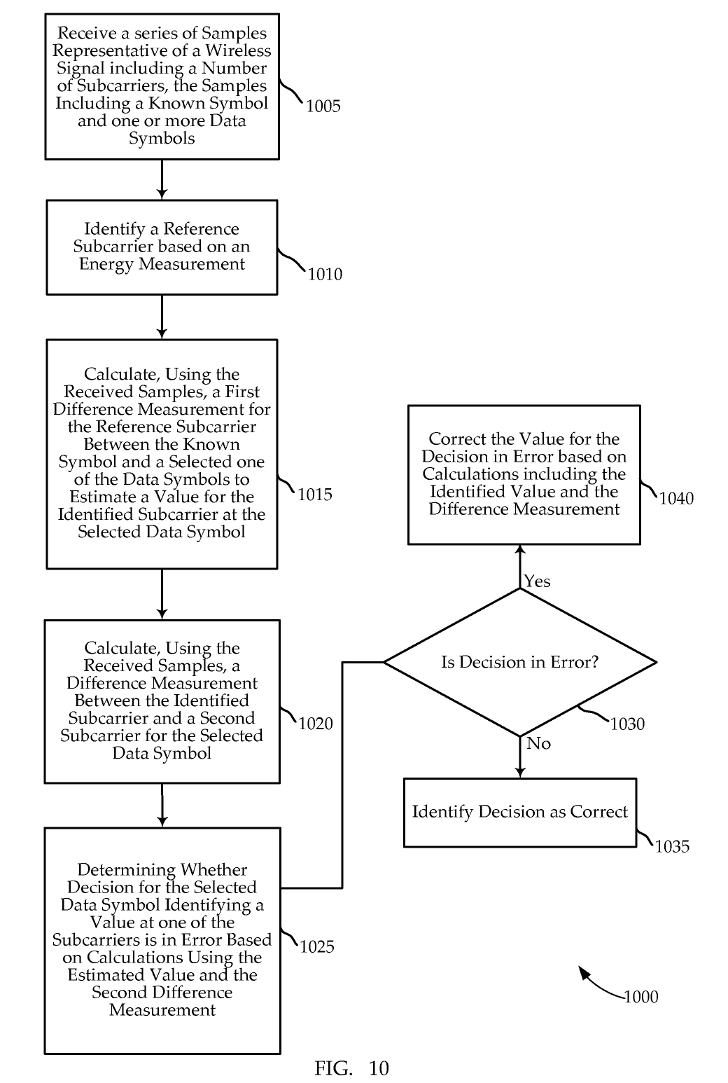

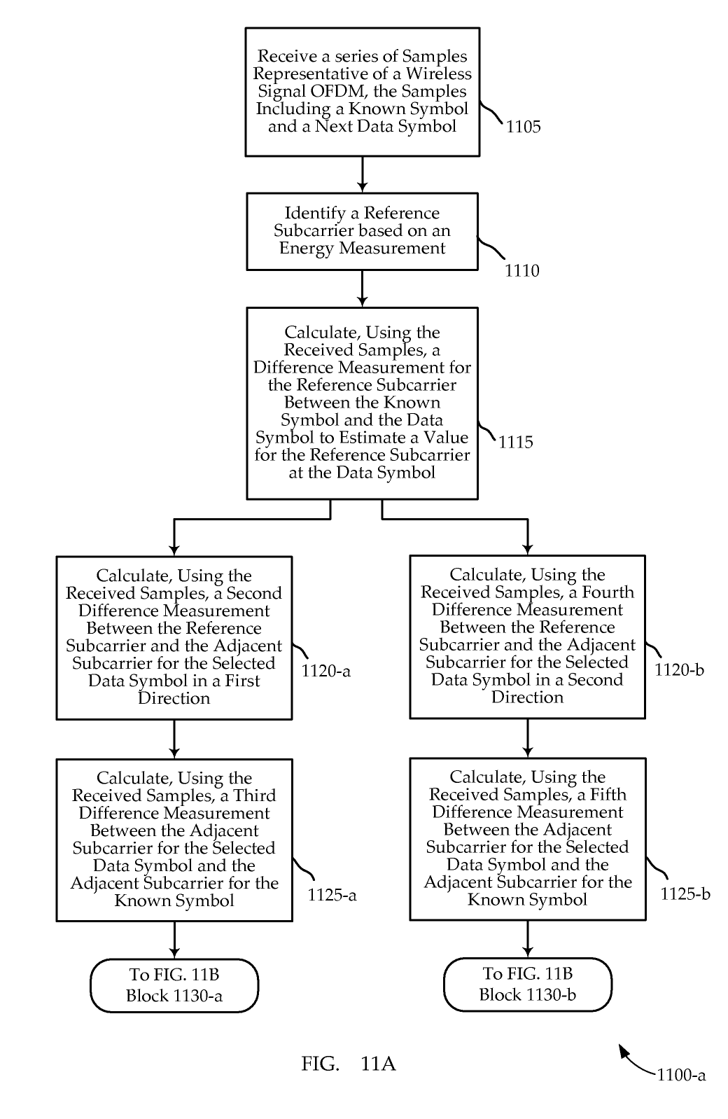

FIG. 10 is a flowchart illustrating a method 1000 of error detection and correction according to various embodiments of the invention. As above, the method 1000 may, for example, be performed in whole or in part on the mobile communications device 105 of FIG. 1 or 2 or, more specifically, the demodulator 220 of FIG. 2 or 4.

At block 1005, a series of samples representative of a wireless signal is received, the samples including a known symbol and one or more data symbols. At block 1010, a reference subcarrier is identified based on an energy measurement. At block 1015, using the received samples, a first difference measurement for the reference subcarrier between the known symbol and a selected one of the data symbols is calculated to estimate a value for the identified subcarrier at the selected data symbol.

At block 1020, using the received samples, a difference measurement between the identified subcarrier and a second subcarrier is calculated for the selected data symbol. At block 1025, a determination is made whether a decision for the selected data symbol identifying a value at one of the subcarriers is in error, the determination based at least in part on one or more calculations using the estimated value and the second difference measurement. At decision block 1030, if the decision is not error, the process flows to block 1035, where the decision is identified as correct. At decision block 1030, if the decision is in error, the value for the decision in error is corrected based on calculations including the identified value and the second difference measurement. The correct or corrected value from block 1035 or 1040 may later be used with additional difference measurements across subcarriers to detect or correct additional errors. Thus, the identified value and the second difference measurement may be used directly, or indirectly, for calculations related to error detection and correction.

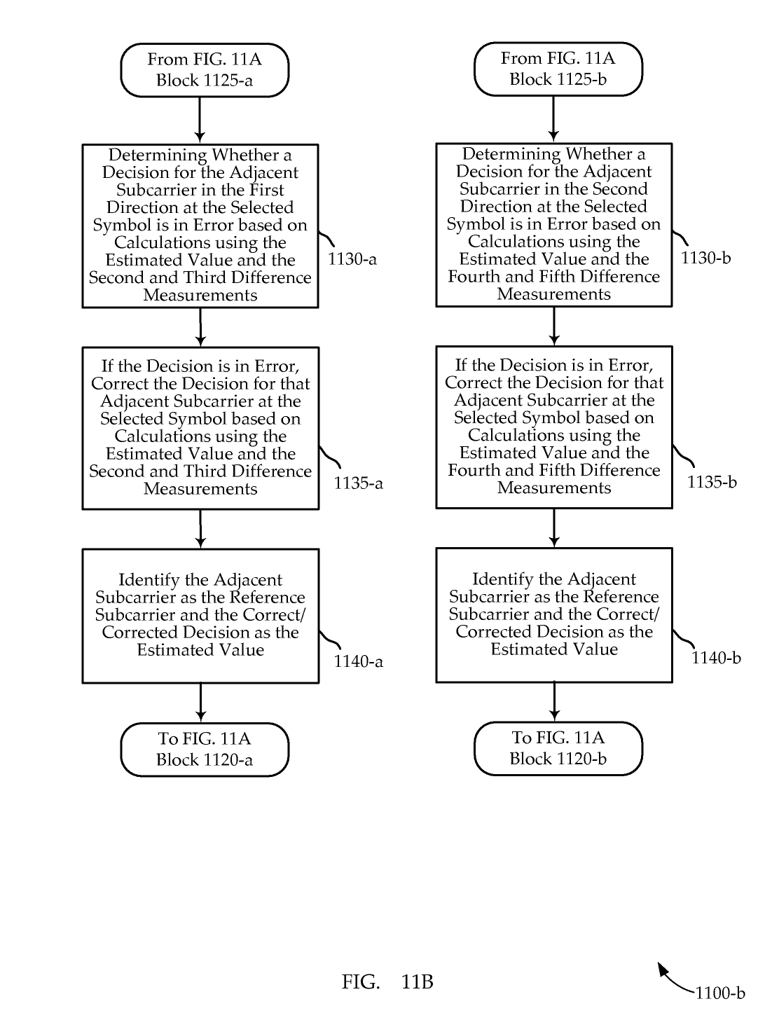

FIGS. 11A-11B are flowcharts illustrating an alternative method 1100 of error detection and correction according to various embodiments of the invention. As above, the method 1100 may, for example, be performed in whole or in part on the mobile communications device 105 of FIG. 1 or 2 or, more specifically, the demodulator 220 of FIG. 2 or 4.

At block 1105, a series of samples representative of a wireless signal OFDM is received, the samples including a known symbol and next data symbols. At block 1110, a reference subcarrier is identified based on an energy measurement. At block 1115, using the received samples, a difference measurement for the reference subcarrier between the known symbol and the data symbol is calculated to estimate a value for the reference subcarrier at the data symbol.

At this point, the process splits in two directions (e.g., as set forth in Table 1). At block 1120-a, using the received samples, a second difference measurement between the reference subcarrier and the adjacent subcarrier in a first direction for the selected data symbol is calculated. At block 1125-a, using the received samples, a third difference measurement between the adjacent subcarrier for the selected data symbol and the adjacent subcarrier for the known symbol is calculated. At block 1130-a, a determination is made whether a decision for the adjacent subcarrier in the first direction at the selected symbol is in error, the determination based on calculations using the estimated value and the second and third difference measurements. At block 1135-a, if the decision is in error, the decision for the adjacent subcarrier at the selected symbol is corrected based on calculations using the identified value and the second and third difference measurements. At block 1140-a, the adjacent subcarrier is identified as the reference subcarrier and the correct/corrected decision as the estimated value. The process then returns to block 1120-a, where the detection and correction process repeats across pairs in the first direction for a number of subcarriers, leveraging previous correct/corrected values and the various difference measurements.

Returning to the split related to the second direction, at block 1120-b, using the received samples, a fourth difference measurement between the reference subcarrier and the adjacent subcarrier in a second direction for the selected data symbol is calculated. At block 1125-b, using the received samples, a fifth difference measurement between the adjacent subcarrier for the selected data symbol and the adjacent subcarrier for the known symbol is calculated. At block 1130-b, a determination is made whether a decision for the adjacent subcarrier in the second direction at the selected symbol is in error, the determination based on calculations using the estimated value and the fourth and fifth difference measurements. At block 1135-b, if the decision is in error, the decision for the second adjacent subcarrier at the selected symbol is corrected based on calculations using the identified value and the fourth and fifth difference measurements. At block 1140-b, the second adjacent subcarrier in the second direction is identified as the reference subcarrier, and the correct/corrected decision is identified as the estimated value. The process then returns to block 1120-b, where the detection and correction process repeats across pairs in the second direction for a number of subcarriers, leveraging previous correct/corrected values and the various difference measurements.

It is worth noting that the functional units and components of the demodulator 220 of FIG. 2 or 4, the time differential calculation unit 405 of FIG. 4 or 5, the frequency differential calculation unit 415 of FIG. 4 or 6, the detection/correction processing unit 420 of FIG. 4 or 7, and the control unit 410 of FIG. 4, 5, 6, or 7 may, individually or collectively, be implemented with one or more Application Specific Integrated Circuits (ASICs) adapted to perform some or all of the applicable functions in hardware. Alternatively, the functions may be performed by one or more other processing units (or cores), on one or more integrated circuits. In other embodiments, other types of integrated circuits may be used (e.g., Structured/Platform ASICs, Field Programmable Gate Arrays (FPGAs), and other Semi-Custom ICs), which may be programmed in any manner known in the art. The functions of each component or unit may also be implemented, in whole or in part, with instructions embodied in a memory, formatted to be executed by one or more general or application-specific processors.

It should be noted that the methods, systems, and devices discussed above are intended merely to be examples. It must be stressed that various embodiments may omit, substitute, or add various procedures or components as appropriate. For instance, it should be appreciated that, in alternative embodiments, the methods may be performed in an order different from that described, and that various steps may be added, omitted, or combined. Also, features described with respect to certain embodiments may be combined in various other embodiments. Different aspects and elements of the embodiments may be combined in a similar manner. Also, it should be emphasized that technology evolves and, thus, many of the elements are examples and should not be interpreted to limit the scope of the invention.

Specific details are given in the description to provide a thorough understanding of the embodiments. However, it will be understood by one of ordinary skill in the art that the embodiments may be practiced without these specific details. For example, well-known circuits, processes, algorithms, structures, and techniques have been shown without unnecessary detail in order to avoid obscuring the embodiments.

Also, it is noted that the embodiments may be described as a process which is depicted as a flow diagram or block diagram. Although each may describe the operations as a sequential process, many of the operations can be performed in parallel or concurrently. In addition, the order of the operations may be rearranged. A process may have additional steps not included in the figure.

Moreover, as disclosed herein, the term “memory” or “memory unit” may represent one or more devices for storing data, including read-only memory (ROM), random access memory (RAM), magnetic RAM, core memory, magnetic disk storage mediums, optical storage mediums, flash memory devices, or other computer-readable mediums for storing information. The term “computer-readable medium” includes, but is not limited to, portable or fixed storage devices, optical storage devices, wireless channels, a sim card, other smart cards, and various other mediums capable of storing, containing, or carrying instructions or data.

Furthermore, embodiments may be implemented by hardware, software, firmware, middleware, microcode, hardware description languages, or any combination thereof. When implemented in software, firmware, middleware, or microcode, the program code or code segments to perform the necessary tasks may be stored in a computer-readable medium such as a storage medium. Processors may perform the necessary tasks.

Having described several embodiments, it will be recognized by those of skill in the art that various modifications, alternative constructions, and equivalents may be used without departing from the spirit of the invention. For example, the above elements may merely be a component of a larger system, wherein other rules may take precedence over or otherwise modify the application of the invention. Also, a number of steps may be undertaken before, during, or after the above elements are considered. Accordingly, the above description should not be taken as limiting the scope of the invention.

What is claimed is:

1. A method of error detection for a wireless signal comprising a plurality of subcarriers, the method comprising:
receiving a plurality of samples representative of the wireless signal, the samples including a known symbol and one or more data symbols;
identifying a reference subcarrier of the plurality of subcarriers based at least in part on an energy measurement;
calculating, using the received samples, a first difference measurement for the reference subcarrier between the known symbol and a selected one of the data symbols to estimate a value for the identified subcarrier at the selected data symbol;
calculating, using the received samples, a second difference measurement between the reference subcarrier and a second subcarrier for the selected data symbol; and
determining a decision for the selected data symbol identifying a value at one of the plurality of subcarriers is in error based at least in part on one or more calculations using the estimated value and the second difference measurement.

2. The method of claim 1, further comprising:
correcting the value for the decision in error at the one subcarrier based at least in part on the estimated value and the second difference measurement.

3. The method of claim 2, further comprising:
calculating a plurality of additional difference measurements between at least a subset of the plurality of subcarriers for the selected data symbol, the subset including the subcarrier with the corrected value; and
determining that decisions for the selected data symbol identifying values at the subset of subcarriers are correct based at least in part on the corrected value and the plurality of additional difference measurements.

4. The method of claim 1, wherein the determining step comprises:
calculating, for the selected data symbol, a plurality of additional difference measurements between the reference subcarrier and the one subcarrier with the decision in error; and
using the additional difference measurements and the estimated value to make a set of decisions for the value attributable to each of the subcarriers between the identified subcarrier and the one subcarrier with the decision in error.

5. The method of claim 1, further comprising:
identifying a second reference subcarrier of the plurality of subcarriers based at least in part on a second energy measurement,
wherein the determination that the decision for the selected data symbol identifying the value at the one of the plurality of subcarriers is in error is also based at least in part on a plurality of additional difference measurements between the second reference subcarrier and the subcarrier with the decision in error.

6. The method of claim 5, wherein,
the additional difference measurements progress in time in a first direction across the plurality of subcarriers from the second reference subcarrier to the subcarrier with the decision in error; and
the direction of difference measurement calculations across subcarriers from the reference subcarrier to the subcarrier with the decision in error is a second direction, opposite from the first direction.

7. The method of claim 1, wherein the determining step comprises:
calculating a plurality of additional difference measurements between the known symbol and the selected data symbol at each of at least a subset of the plurality of subcarriers,
wherein the determination that the decision for the selected data symbol identifying the value at the one of the plurality of subcarriers is in error is also based at least in part on the plurality of additional difference measurements.

8. The method of claim 1, wherein:
the first difference measurement comprises a product of a first version of a sample representative of the reference subcarrier at the known symbol and a second, conjugate version of a sample representative of the reference subcarrier at the selected data symbol; and
the received wireless signal comprises an orthogonal frequency-division multiplexing (OFDM) signal.

9. The method of claim 1, wherein:
the second difference measurement comprises a product of a first version of a sample representative of the reference subcarrier at the selected data symbol and a second, conjugate version of a sample representative of a second, adjacent subcarrier at the selected data symbol; and
the received wireless signal comprises a burst of a digital video broadcast signal.

10. The method of claim 1, further comprising,
operating in a first mode wherein the known symbol comprises a first pilot signal for a first standard of a plurality of standards; and
operating in a second mode wherein the known symbol comprises a second pilot signal for a second standard of the plurality of standards, wherein only a subset of the plurality of subcarriers is known for the second pilot signal.

11. A device for error detection for a wireless signal comprising a plurality of subcarriers, the device comprising:
a receiving unit configured to receive a plurality of samples representative of the wireless signal, the samples including a known symbol and one or more data symbols;
a time differential calculation unit, communicatively coupled with the receiving unit, and configured to:
identify a subcarrier of the plurality of subcarriers to serve as a reference subcarrier; and
calculate, using the received samples, a first difference measurement for the identified subcarrier between the known symbol and a selected one of the data symbols to estimate a value for the reference subcarrier at the selected data symbol;
a frequency differential calculation unit, communicatively coupled with the time differential calculation unit, and configured to calculate a second difference measurement between the reference subcarrier and a second subcarrier for the selected data symbol using the received samples; and
an error detection unit, communicatively coupled with the frequency differential calculation unit, and configured to determine whether a decision identifying a value for the selected data symbol is in error based at least in part on one or more calculations using the estimated value and the second difference measurement.

12. The device of claim 11, further comprising:
a correction unit, communicatively coupled with the error detection unit, and configured to correct the value for a subcarrier with a decision in error after the error detection unit determines the error occurs.

13. The device of claim 12, wherein,
the frequency differential calculation unit is further configured to calculate a plurality of additional difference measurements for the subset of the plurality of subcarriers between the second subcarrier and the subcarrier with the decision in error for the selected data symbol; and
the error detection unit is further configured to perform calculations using the estimated value, the second difference measurement, and the plurality of additional difference measurements to make decisions on a value for each of the plurality of subcarriers between the second subcarrier and the subcarrier with the decision in error.

14. The device of claim 11, wherein,
the receiving unit is further configured to:
determine that a signal strength measurement of the wireless signal is less than a minimum threshold; and
transmit a control signal to cause the frequency differential calculation unit to calculate the second difference measurement based at least in part on the determination,
wherein the frequency differential calculation unit is configured to forego calculation of the second difference measurement when the measurement of the wireless signal meets or exceeds the minimum threshold.

15. The device of claim 11, wherein,
the time differential calculation unit is configured to identify a second reference subcarrier of the plurality of subcarriers; and
the error detection unit is further configured to determine whether the decision for the selected data symbol identifying the value is in error based at least in part on a plurality of additional difference measurements between the second reference subcarrier and the subcarrier with the decision in error.

16. The device of claim 11, wherein the time differential calculation unit is further configured to:
calculate a plurality of additional difference measurements between the known symbol and the selected data symbol at each of at least a subset of the plurality of subcarriers,
wherein the determination whether the decision for the selected data symbol identifying the value is in error is also based at least in part on the plurality of additional difference measurements.

17. A method of error detection for a wireless signal comprising a plurality of subcarriers, the method comprising:
receiving a plurality of samples representative of the wireless signal, the samples including a plurality of symbols;
identifying a subcarrier of the plurality of subcarriers to serve as a reference subcarrier;
identifying a value for the reference subcarrier at a selected one of the plurality of symbols;
calculating, using the received samples, a difference measurement between the identified subcarrier and a second subcarrier for the selected symbol; and
determining whether a decision for a value at one or more of the subcarriers at the selected symbol is in error based at least in part on the identified value and the difference measurement.

18. The method of claim 17, further comprising:
correcting the value for the decision in error at the one subcarrier based at least in part on the identified value and the second difference measurement.

19. The method of claim 17, wherein:
the identification of the reference subcarrier is based at least in part on an energy measurement;
the value for the reference subcarrier at the selected symbol is identified by calculating, using the received samples, a second difference measurement for the reference subcarrier between a previous symbol and the selected data symbol; and
a value for the subcarrier at the previous symbol is identified using a third difference measurement between the reference subcarrier and a second subcarrier for the previous symbol.

20. The method of claim 17, further comprising:
calculating a plurality of additional difference measurements between at least a subset of the plurality of subcarriers for the selected symbol; and
determining that decisions for the selected data symbol identifying values at the subset of subcarriers are correct based at least in part on calculations using the identified value and the plurality of additional difference measurements.

21. The method of claim 17, further comprising:
identifying a second reference subcarrier of the plurality of subcarriers; and
calculating, across a first subset of the plurality of subcarriers in a first direction, a plurality of additional difference measurements between the second reference subcarrier and the subcarrier associated with the determination,
wherein the direction of calculations across subcarriers from the reference subcarrier to the subcarrier associated with the determination is a second direction, opposite from the first direction.

22. The method of claim 1, wherein the determining step comprises:
calculating a plurality of additional difference measurements between a previous symbol and the selected symbol at each of at least a subset of the plurality of subcarriers,
wherein a determination whether the decision for the selected data symbol identifying the value at the one of the plurality of subcarriers is in error is also based at least in part on the plurality of additional difference measurements.

23. A device for error detection for a wireless signal comprising a plurality of subcarriers, the device comprising:
a receiving unit configured to receive a plurality of samples representative of the wireless signal, the samples including a plurality of symbols;
a control unit, communicatively coupled with the receiving unit, and configured to:
identify a subcarrier of the plurality of subcarriers to serve as a reference subcarrier based on a measurement of signal strength across the plurality of subcarriers; and
identify a value for the reference subcarrier at a selected one of the plurality of symbols;
a frequency differential calculation unit, communicatively coupled with the control unit, and configured to calculate, using the received samples, a difference measurement between the identified subcarrier and a second subcarrier for the selected symbol; and
an error detection unit, communicatively coupled with the frequency differential calculation unit, and configured to determine whether a decision for one or more of the subcarriers at the selected data symbol is in error based at least in part on the identified value and the difference measurement.

24. The device of claim 23, wherein the control unit comprises:
a time differential calculation unit configured to calculate, using the received samples, a difference measurement for the reference subcarrier between the selected symbol and a previous symbol to identify a value for the reference subcarrier at the selected symbol.

25. A method of error correction for a wireless signal comprising a plurality of subcarriers, the method comprising:
receiving a plurality of samples representative of the wireless signal, the samples including a plurality of symbols;
identifying a subcarrier of the plurality of subcarriers to serve as a reference subcarrier;
identifying a value for the reference subcarrier at a selected one of the plurality of symbols;
calculating, using the received samples, a difference measurement between the identified subcarrier and a second subcarrier for the selected symbol; and
correcting a decision for the selected symbol based at least in part on the identified value and the difference measurement.
